(19) United States
(12) Patent Application Publication
(10) Pub. No.: US 2002/0176590 A1
(43) Pub. Date: Nov. 28, 2002

(54) Variable signal attenuating circuit

(76) Inventor: Jun Honda, Tokorozawa-City (JP)

Correspondence Address: MCGINN & GIBB, PLLC, 8321 OLD COURTHOUSE ROAD, SUITE 200, VIENNA, VA, 22182-3817, US

(21) Appl. No.: 10/153,735

(22) Filed: May 24, 2002

(30) Foreign Application Priority Data
May 28, 2001 (JP) 2001-159424

(51) Int. Cl. H03G 7/00

(52) U.S. Cl. 381/106; 381/104; 333/14

(57) ABSTRACT

A variable signal attenuating circuit which has a function of preventing dropout of an attenuated signal even if a large attenuation value is set. A dynamic range compression processing unit is provided in an input unit of the variable signal attenuating circuit for compressing the dynamic range of an input signal within a predetermined range in accordance with a set attenuation value, such that the signal passing through the compression processing unit is attenuated by the set attenuation value.

### BACKGROUND OF THE INVENTION

1. Field of the Invention

The present invention relates to a variable signal attenuating circuit for use in an audio device such as a stereo, a television or the like.

2. Description of the Related Art

In an audio device such as a stereo, a television or the like, a variable signal attenuating circuit is typically used for adding an attenuation to an audio signal to be treated.

When an attenuation value set in the variable signal attenuating circuit is extremely large, an audio signal having passed through the variable signal attenuating circuit is excessively reduced in level, thereby causing inconveniences. In the case of a digital audio signal, no signal appear at the output of the variable signal attenuating circuit. Otherwise, the reproduced sound is so distorted. When, on the other hand, an analog audio signal is concerned, a reproduced signal is masked by noises, causing troubles such as difficulties experienced by a listener in listening to the reproduced signal.

Particularly, the number of bit of digital signals is finite in a digital variable signal attenuating circuit for use in a digital audio system, so that a bit utilization rate is lower as the attenuating circuit applies a larger amount of attenuation, thereby making the foregoing harmful influences more prominent.

### OBJECT AND SUMMARY OF THE INVENTION

The present invention has been conceived so as to eliminate the disadvantages mentioned above, and it is an object of the invention to provide a variable signal attenuating circuit which is capable of adjusting an output signal level in accordance with a set attenuation value.

The present invention provides a variable signal attenuating circuit for use in an audio device. The variable signal attenuating circuit includes attenuation value setting part for setting a predetermined attenuation value, dynamic range compression processor for compressing a dynamic range of an input signal within a predetermined range, and signal attenuator for attenuating the input signal which has passed through the dynamic range compression processor based on the attenuation value, wherein the dynamic range compression processor determines a compressed range based on the attenuation value when compressing the dynamic range of the input signal within the predetermined range.

### BRIEF DESCRIPTION OF THE DRAWINGS

FIG. 1 is a block diagram illustrating a configuration of the present invention;

FIG. 2 is a block diagram illustrating a first embodiment of the present invention;

FIG. 3 is a diagram showing a signal conversion table in the embodiment illustrated in FIG. 2;

FIG. 4 is a graph showing a level conversion for input/output signals in the embodiment illustrated in FIG. 2;

FIGS. 5A and 5B are explanatory diagrams for an effect produced by compressing the dynamic range of a signal;

FIG. 6 is a block diagram illustrating a second embodiment of the present invention; and

FIG. 7 is a table showing the relationship between an attenuation value and a dynamic range in the embodiment illustrated in FIG. 6.

### DETAILED DESCRIPTION OF THE EMBODIMENTS

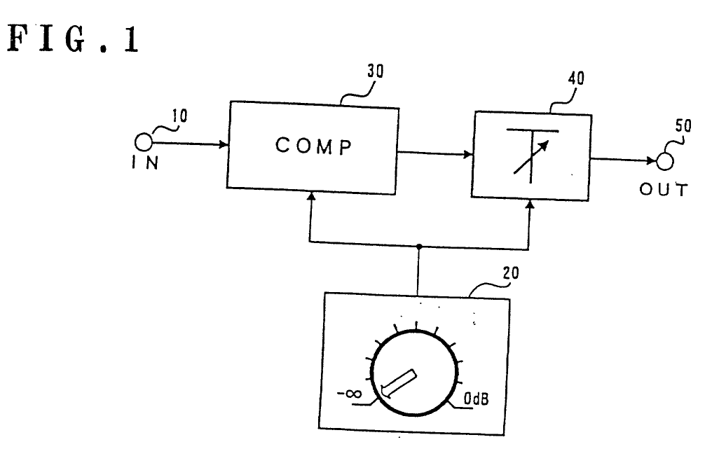

FIG. 1 is a block diagram illustrating a configuration of a variable signal attenuating circuit according to the present invention.

In FIG. 1, an input terminal 10 is provided for introducing an input signal into the circuit. The input signal may be an ordinary analog signal which is an electric signal simply converted from an audio signal such as music, voice and the like, or a digital signal produced by applying the analog signal with treatments of sampling, quantization or the like.

An attenuation value input part 20 is provided which is handled by a user of an audio device equipped with this attenuation circuit so as to input a desired signal attenuation value for adjusting the volume of an audio output signal as required. While FIG. 1 illustrates a so-called volume for conceptually representing such an attenuation setting operational procedure, the attenuation value may be set, for example, using input means such as a keyboard, a particular function key, or the like.

A dynamic range compression processing part (hereinafter simply called the “compression processing part”) 30 is provided for compressing the dynamic range of an input signal supplied from the input terminal 10 in accordance with an attenuation value supplied through the attenuation value input part 20.

A signal attenuator 40 is provided for attenuating a signal, which has passed the compression processing part 30, in accordance with the attenuation value supplied via the attenuation input part 20 without affecting input and output impedances.

An output terminal 50 is provided which relays an attenuated signal, which has passed the signal attenuator 40, to another audio equipment which is the next stage of the attenuating circuit.

Next, the configuration illustrated in the block diagram of FIG. 1 will be described below in detail.

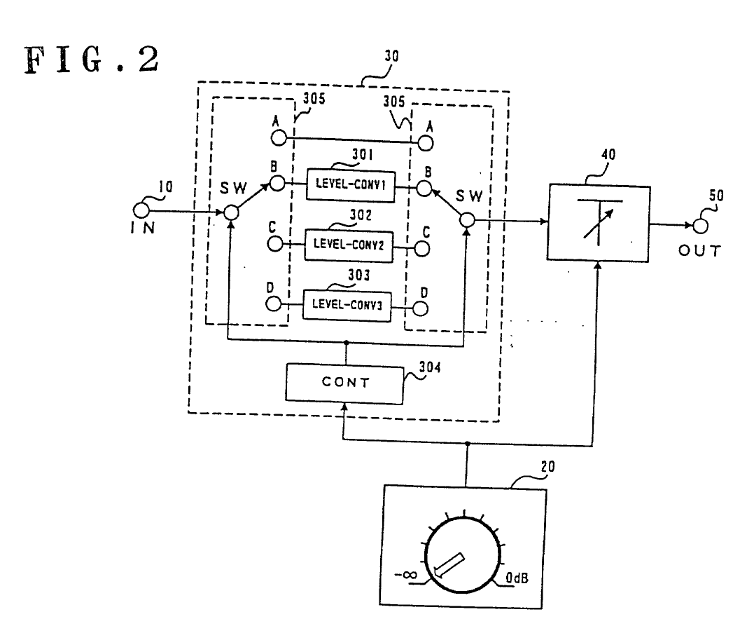

In FIG. 2, the compression processing part 30 comprises signal level conversion tables (hereinafter simply called the “conversion tables”) 301-303; a control circuit 304; and a signal level conversion table switching circuit (hereinafter simply called the “switching circuit”) 305. These circuits 301-305 may be based on a microcomputer which comprises a CPU, and memory elements such as a ROM (Read Only Memory), a RAM (Random Access Memory), and the like.

The conversion tables 301-303 may be implemented by a storage device, for example, a ROM or the like. Namely the conversion table is adapted to produce a certain output value in response to a certain input value.

The switching circuit 305 is adapted to select one of the conversion tables for use in response to a control instruction from the control circuit 304 and supplying an input signal to the selected table.

The operation of the embodiment illustrated in FIG. 2 will be described below.

First, the control circuit 304 reads an attenuation value β dB set in the attenuation value input part 20 to select a conversion table corresponding to the attenuation value. For the correspondence of the attenuation value to a conversion table, relationships, for example, shown below, may be previously assigned:

When β=0 dB ; No Conversion Table

When β<30 dB; Conversion Table 301

When β<60 dB; Conversion Table 302

When β<90 dB; Conversion Table 303

As appreciated, the division of the attenuation value β into how many sections, or the number of conversion tables is not limited to this embodiment, and the number of used conversion tables may be increased to divide the attenuation value β into a larger number of sections.

As the control circuit 304 selects a conversion table corresponding to the attenuation value β from the conversion tables 301-303, the control circuit 304 supplies the switching circuit 305 with a switching instruction for selecting the conversion table. As a result of this processing, the input signal via the input terminal 10 is supplied to the selected conversion table.

Now, description will be made on the conversion processing for an input signal level using the conversion tables. Assume in the following description that the input level is represented by a digital value which is quantized in a predetermined format.

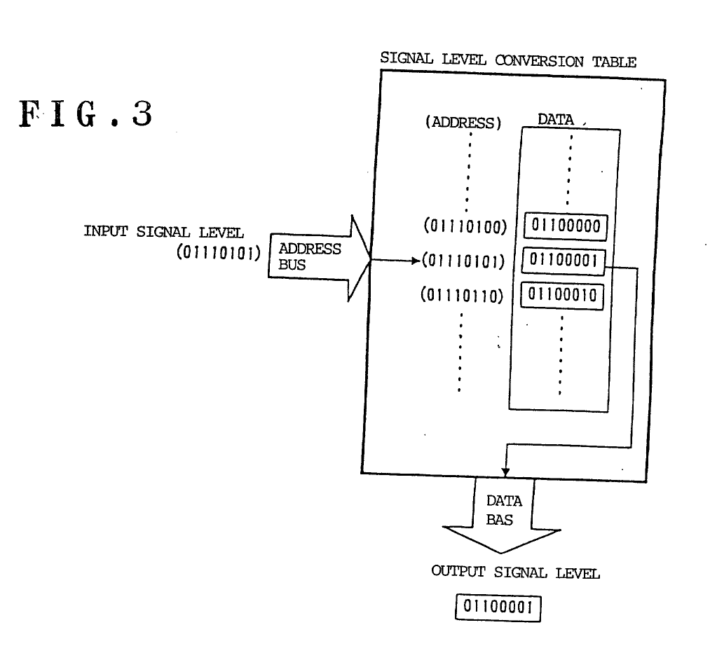

As described above, each of the conversion tables in this embodiment may be any circuit which outputs a predetermined constant output signal level in response to a predetermined input signal level in a one-to-one correspondence. This can be implemented, for example, by using a storage device such as a ROM, as shown in FIG. 3. Specifically, this can be implemented by adding the input signal level to an address bus of the storage device as an address signal, and extracting data stored at the address in the storage device from a data bus of the storage device as an output signal level.

When an input signal from the input terminal 10 is an analog signal, the foregoing processing should be performed after converting the input signal into a digital signal by an analog/digital converter (not shown).

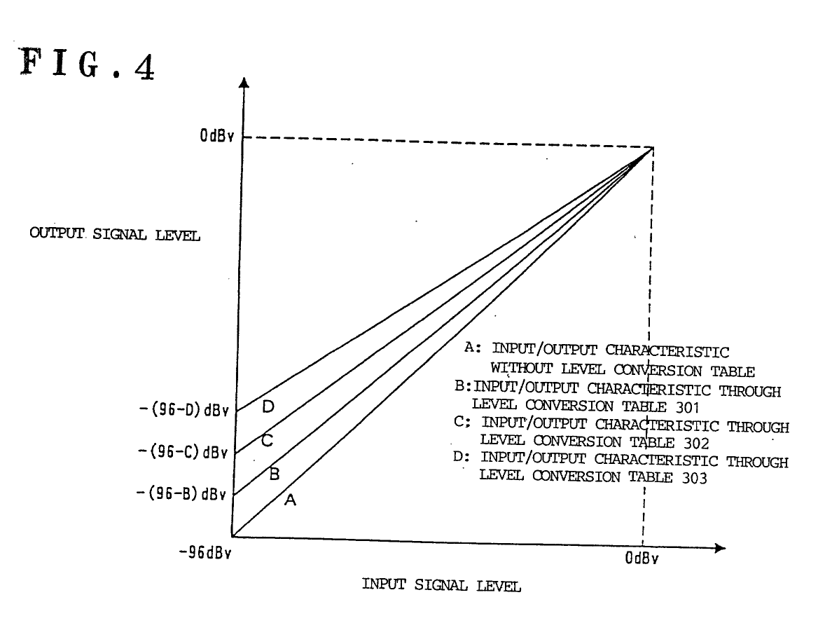

Next, the principles of the signal dynamic range compression through the signal level conversion processing will be described with reference to an input/output signal level conversion graph shown in FIG. 4.

While the signal level conversion processing is digitally performed using, for example, a ROM table as described above, the following description will be made using an analog value as a signal level for facilitating the understanding of the signal dynamic range compression through the signal level conversion processing.

In FIG. 4, a signal level conversion line A indicates the correspondence of the input signal level to the output signal level when an input signal level is not converted, i.e., when the switch of the switching circuit 305 is at a position A in the embodiment of FIG. 2. In this case, an input signal from the input terminal 10 simply passes through the compression processing part 30, so that the input to the compression processing part 30 is equal in signal level to the output from the compression processing case 30. When, therefore, the input signal level is, for example, at −20 dBv, the output signal level is also at −20 dBv, without a change in the signal dynamic range between the input and output of the compression processing part 30. In other words, the dynamic range of the output signal from the compression processing part 30 remains at 96 dB which is equal to the dynamic range of the input signal, as shown in FIG. 4.

While the dynamic range of the input signal is assumed to extend over 96 dB from 0 dBv to −96 dBv of the absolute signal level, it should be understood that this embodiment is not limited to these values, and a variety of values may be taken under design conditions.

Next, a signal level conversion line B in FIG. 4 will be described. When the signal level conversion line B is applied, the signal level is converted using the conversion table 301. Specifically, the signal level conversion line B indicates the correspondence of the input signal level to the output signal level when the switch of the switching circuit 305 is at a position B. As is also apparent from FIG. 4, in this case, the output signal level of the compression processing part 30 is amplified by B dB at a minimum value (−96 dBv) of the input signal level.

Specifically, the output signal level is also at 0 dBv when the input signal level is at 0 dBv, whereas the output level is at (−96+B) dBv when the input signal level is at −96 dBv. When the input signal level is between 0 dBv and −96 dBv, an output signal level found determined from the signal level conversion line B appears at the output of the compression processing part 30. As a result, the dynamic range of the output signal is compressed by B dB as compared with that of the input signal.

In the following, with the signal level conversion line C, the signal level is converted using the conversion table 302 in a similar manner, and the dynamic range of the converted output signal level is compressed by C dB. Likewise, with the signal level conversion line D, the dynamic range of the converted output signal level is compressed by D dB by using the conversion table 303.

In this embodiment, the relationship of:

(−96+D) dBv>(−96+C) dBv>(−96+B) dBv

is established as shown in FIG. 4. Therefore, the dynamic range of the signal is compressed more in the order of the conversion lines B, C, D, i.e., in the order of the used conversion tables 301, 302, 303.

In other words, as a larger attenuation value β is set in the attenuation value input part 20, a bias value is increased at the minimum value of the input signal level on the signal level conversion line, resulting in a more compressed dynamic range of the output signal.

The signal output from the compression processing part 30 is attenuated by the signal attenuator 40 based on the attenuation value set in the attenuation value input part 20, and then output to the succeeding audio equipment through the output terminal 50.

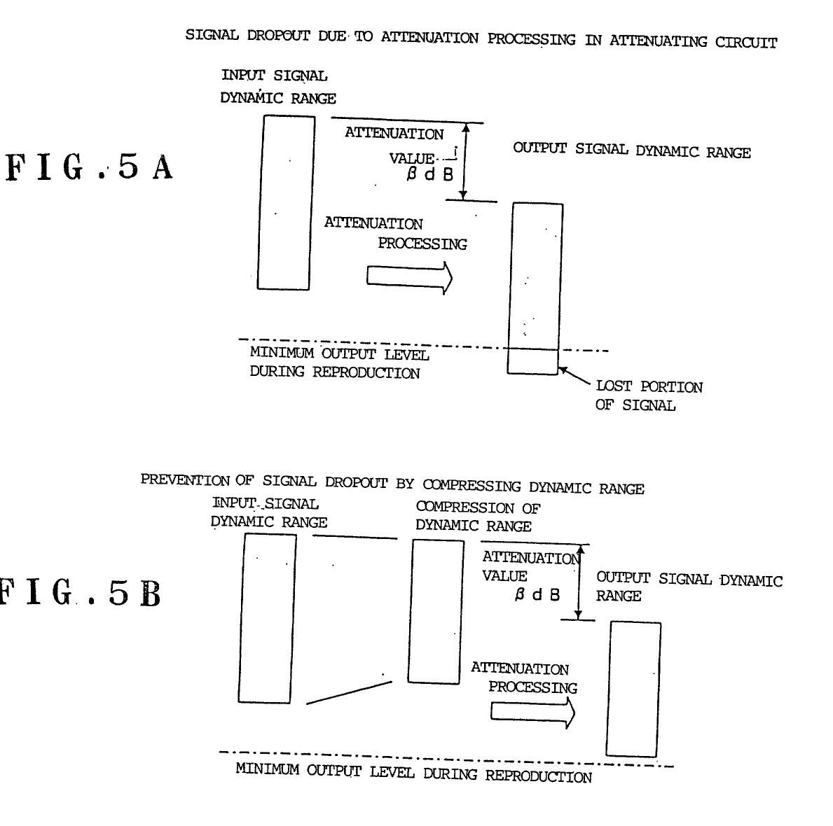

In a conventional variable attenuating circuit, when the user sets a large attenuation value, a lower part of the dynamic range of an attenuated signal may be below a minimum output level when the audio signal is reproduced, as shown in FIG. 5A, in which case the signal at a level below the minimum output level will be lost during reproduction.

On the other hand, in this embodiment, the dynamic range of an input signal is compressed in accordance with an attenuation value set by the user before the input signal is attenuated in the variable attenuating circuit. Therefore, as shown in FIG. 5B, a lower portion of the dynamic range after attenuation is less likely to be below a minimum output level during signal reproduction, thereby making it possible to prevent dropout of the signal.

When the user sets an even larger attenuation value, the dynamic range cannot be compressed by a thoughtlessly large amount for preventing unnaturalness in a reproduced audio signal, thereby possibly causing the dropout of signal during the reproduction. However, even in such a case, it is possible to largely prevent the dropout of signal as compared with an uncompressed dynamic range.

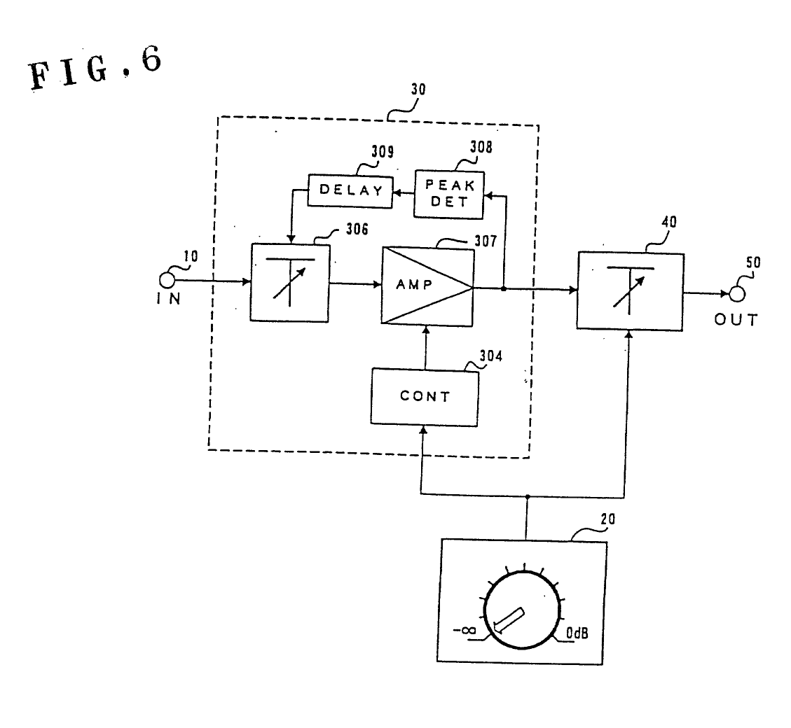

Next, FIG. 6 illustrates a second embodiment of the variable signal attenuating circuit in the block diagram of FIG. 1.

In FIG. 6, a compression processing part 30 comprises a control circuit 304; a variable attenuating circuit 306; a variable amplifying circuit 307; a peak detecting circuit 308; and a delay circuit 309.

The control circuit 304 is formed by a microcomputer for governing the overall operation of the compression processing part 30.

The variable attenuating circuit 306 and variable amplifying circuit 307 are connected in cascade, where the variable attenuating circuit 306 attenuates an input signal supplied via an input terminal 10, while the variable amplifying circuit 307 gives a gain to the input signal.

The peak detecting circuit 308 monitors an output level of the variable amplifying circuit 307, and supplies a control instruction to the variable attenuating circuit 306 when it detects a peak level which exceeds a predetermined threshold value. The delay circuit 309 gives a constant delay to a control instruction from the peak detecting circuit 308 to the variable attenuating circuit 306.

The operation of the embodiment illustrated in FIG. 6 will be described below.

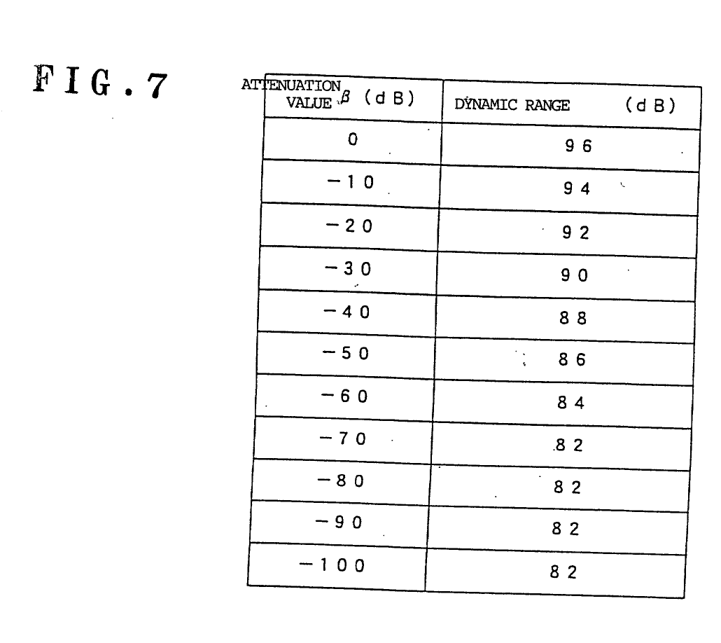

First, the control circuit 304 reads an attenuation value β set in the attenuation value input part 20 to select a dynamic range of a signal corresponding to the attenuation value. The relationship between the attenuation value β and the dynamic range may be previously specified, for example, in a table as shown in FIG. 7, such that the table is searched from the read value of β to find an associated dynamic range.

According to FIG. 7, the dynamic range is 84 dB when β=−60 dB, thus producing a difference of 12 dB with respect to 96 dB which is assumed as the dynamic range of the input signal in this embodiment. Therefore, the control circuit 304 supplies a control instruction to the variable amplifying circuit 307 for amplifying the dynamic range by the difference to provide the dynamic range of 84 dB.

In this manner, the input signal level is uniformly increased by 12 dB, so that if the input signal level is originally high, the resulting signal level could exceed the upper limit value of 0 dBv of the dynamic range in this embodiment. To solve this problem, the peak detecting circuit 308 monitors the output level of the variable amplifying circuit 307 at all times to output a control instruction to the variable attenuating circuit 306 to promptly increase an attenuation value in this circuit when the output level exceeds the threshold value. In addition, for preventing auditory discomfort due to sudden fluctuations in the signal level caused by such feedback, a delay time is provided by the delay circuit 309 to the propagation of the control instruction.

As a result of the foregoing processing, the output signal level from the compression processing part 30 has its upper limit value restricted to 0 dBv, and its lower limit value set to −84 dBv which is the result of adding a bias of +12 dB to the lower limit value of the dynamic range of the input signal, i.e., −96 dBv. This is nothing but the compression, the dynamic range of 96 dB of the input signal is compressed by 12 dB.

In this embodiment, the input signal from the input terminal 10 is attenuated in the signal attenuator 40 by an attenuation value set in the attenuation value input part 20 after the input signal is compressed. It is therefore possible to provide the same result as that described in connection with FIG. 5 in the aforementioned embodiment.

Since, according to the present invention, the input signal is attenuated after its dynamic range is narrowed down in accordance with a set attenuation value, the signal will not disappear due to the attenuation even if the signal is at a low level.

Since, furthermore, the amount of compressed dynamic range is determined in accordance with a table which relates an attenuation value to the dynamic range in a predetermined manner, a change in sound quality is advantageously small even when the signal is at a high level.

Since, still further, the single level is applied with a bias to compress the dynamic range, a further effect can be produced in that low level signals are easy to hear.

This application is based on a Japanese Patent Application No. 2001-159424 which is hereby incorporated by reference.

What is claimed is:

1. A variable signal attenuating circuit for use in audio equipment, comprising:
attenuation value setting part for setting a predetermined attenuation value;
dynamic range compression processing part for compressing a dynamic range of an input signal within a predetermined range; and
signal attenuating part for attenuating the input signal which has passed through said dynamic range compression processing part based on said attenuation value,
wherein said dynamic range compression processing part determines a compressed range based on said attenuation value when compressing the dynamic range of the input signal within the predetermined range.

2. A variable signal attenuating circuit according to claim 1, wherein said dynamic range compression processing part includes:
level converting part for converting the level of the input signal in accordance with a specified one of a plurality of level conversion functions different from one another; and
specifying part for specifying one of said level conversion functions in accordance with the magnitude of an attenuation value set by said attenuation value setting part.

3. A variable signal attenuating circuit according to claim 2, wherein each of said plurality of level conversion functions is represented by a plurality of conversion tables corresponding thereto.

4. A variable signal attenuating circuit according to claim 2, wherein said level conversion functions are linear functions which specify the magnitude of the input signal as a parameter.

5. A variable signal attenuating circuit according to claim 2, wherein said level conversion functions have respective maximum function values equal to one other.
